(19) United States
(12) Patent Application Publication
(10) Pub. No.: US 2024/0352621 A1
(43) Pub. Date: Oct. 24, 2024

(54) NANOCRYSTALLINE DIAMOND WITH AMORPHOUS INTERFACIAL LAYER

(71) Applicant: Applied Materials, Inc., Santa Clara, CA (US)

(72) Inventors: Sze Chieh Tan, Singapore (SG); Vicknesh Sahmuganathan, Singapore (SG); Christian W. Valencia, Alhambra, CA (US); Thai Cheng Chua, Cupertino, CA (US); Masahiro Kawasaki, San Jose, CA (US); Jenn-Yue Wang, Santa Clara, CA (US); John Sudijono, Singapore (SG)

(73) Assignee: Applied Materials, Inc., Santa Clara, CA (US)

(21) Appl. No.: 18/137,069

(22) Filed: Apr. 20, 2023

(51) Int. Cl. C30B 29/04; C30B 25/10; C30B 25/18

(52) U.S. Cl. CPC C30B 29/04; C30B 25/10; C30B 25/186

(57) ABSTRACT

Methods of depositing a nanocrystalline diamond film are described. The method may be used in the manufacture of integrated circuits. Methods include treating a substrate with a plasma to form a treated substrate surface, incubating the treated substrate with a carbon-rich plasma to nucleate diamond particles on the treated substrate surface, followed by treating the substrate with a plasma to form a nanocrystalline diamond film. The resulting nanocrystalline diamond films are formed on an interfacial oxide-rich amorphous layer between the nanocrystalline diamond film and a silicon substrate.

### TECHNICAL FIELD

Embodiments of the present disclosure pertain to the field of electronic device manufacturing, and, in particular, to integrated circuit (IC) manufacturing. More particularly, embodiments of the disclosure provide methods of depositing diamond-like carbon hard mask films on amorphous interfacial layers. Film stacks comprising diamond-like carbon directly on an amorphous layer which is directly on a substrate are also disclosed.

### BACKGROUND

As the semiconductor industry introduces new generations of integrated circuits (ICs) having higher performance and greater functionality, the density of the elements that form those ICs is increased, while the dimensions, size, and spacing between the individual components or elements are reduced. While in the past, such reductions were limited only by the ability to define the structures using photolithography, device geometries having dimensions measured in μm or nm have created new limiting factors such as the conductivity of the metallic elements, the dielectric constant of the insulating material(s) used between the elements, or challenges in 3D-NAND or DRAM processes. These limitations may be addressed by more durable and higher hardness hard masks.

Diamond is a material with high hardness, chemical inertness, high thermal conductivity, and good optical transparency, making it promising in microelectronic applications. Diamond has emerged as a promising candidate for a myriad of microelectronic applications.

The large discrepancy in the surface energies of diamond and silicon (6 J cm⁻² vs. 1.5 J cm⁻²), low sticking coefficients of the gaseous precursors (e.g., hydrocarbon radicals) and strong competition from the nondiamond phases, however, typically result in poor diamond nucleation density (˜10⁴ cm⁻²) on untreated silicon.

To address poor diamond nucleation density, the substrate is usually pre-treated (e.g., mechanical abrasion or micro-chipping) and/or seeded with nano-diamond (ND) particles prior to deposition. Such seeding methods, however, consist of multiple solution-based procedures which are cumbersome and not cleanroom compatible.

Alternatively, Bias-enhanced nucleation (BEN) is one of the few nucleation techniques that can be performed in-situ. It involves the bombardment of methane-rich (4-10%) ionized gas species on the surface of a negatively-charged biased substrate, allowing the formation of a carbide layer with improved substrate adhesion. With BEN, nucleation densities greater than 10¹¹ cm⁻² had been reported. Unfortunately, the application of BEN is limited by the presence of substrate surface damages (e.g., in the form of holes as deep as 2-3 μm in diameter), difficulty in applying bias uniformly over large areas, and the need for a conductive substrate.

For both seeding technologies and BEN, several researchers have reported the presence of a carbon-rich interfacial layer between the nano-crystalline diamond (NCD) film and the substrate. A working theory was that such carbon-rich interfacial layer is crucial to the subsequent formation of diamond nuclei. While the role of SiC in diamond nucleation is not yet understood, it is generally agreed that such interfacial layer consists mainly of silicon and carbon with minimal oxygen (<10¹⁹ cm⁻³ or 0.1 atomic percent).

Oxides, particularly silicon oxides are far better understood and more widely used than silicon carbides. Accordingly, there is a need for methods of forming the nanocrystalline diamond (NCD) films on oxygen-containing materials.

### SUMMARY

One or more embodiments of the disclosure are directed to a method of forming a nanocrystalline diamond film. The method comprises exposing a silicon substrate to a first plasma from a first plasma source. The first plasma source comprising one or more of CₓH_{y} wherein y≥x, carbon dioxide (CO₂), hydrogen (H₂), nitrogen (N₂), and argon (Ar) to provide a treated substrate. The treated substrate is incubated with a gas stream comprising a hydrocarbon and a second plasma to nucleate diamond particles and form a seeded substrate. The seeded substrate is exposed to a third plasma having a power greater than 50 W to form a nanocrystalline diamond film. After formation of the nanocrystalline diamond film, the nanocrystalline diamond film is directly on an oxide-rich amorphous layer which is directly on the silicon substrate.

Additional embodiments of the disclosure are directed to a method of forming a diamond film. The method comprises exposing a treated substrate to a gas stream comprising a hydrocarbon to nucleate diamond particles on a top surface of the substrate. The substrate comprises an exposed amorphous oxide-rich layer. The diamond particles are exposed to a plasma having a power greater than 50 W to form a nanocrystalline diamond film on the top surface of the substrate, which is not silicon.

Further embodiments of the disclosure are directed to an electronic device comprising: a silicon substrate, an amorphous oxide layer directly on the silicon substrate, and a nanocrystalline diamond film directly on the amorphous oxide layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method for depositing a nanocrystalline diamond film according to one or more embodiments; and

FIGS. 2A-2E illustrate a schematic cross-sectional view of a substrate within a processing chamber during processing according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the terms “precursor,” “reactant,” “reactive gas” and the like are used interchangeably to refer to any gaseous species that can react with the substrate surface.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface before, during or after the disclosed methods.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like.

In some embodiments, the substrate comprises a dielectric. In some embodiments, the substrate comprises or consists essentially of silicon. In some embodiments, the substrate comprises or consists essentially of silicon oxide, silicon nitride or silicon carbide. In some embodiments, the substrate is not a silicon substrate. In some embodiments, the substrate is substantially free of any native oxides before being processed according to the disclosed methods. As used in this regard, as substrate which is “substantially free of any native oxide” contains less than 2 percent oxygen atoms of the surface atoms of the substrate material. In some embodiments, the substrate is cleaned of surface oxides before being processed by the disclosed methods.

In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used in this disclosure and the appended claims, the term “on”, with respect to a film or a layer of a film, includes the film or layer being directly on a surface, for example, a substrate surface, as well as there being one or more underlayers between the film or layer and the surface, for example the substrate surface. Thus, in some embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

As used herein, the phrase “nanocrystalline diamond” refers a solid film of diamond grown on a substrate (e.g., silicon). In one or more embodiments, nanocrystallinity is the result of the enhanced re-nucleation reaction in diamond growth, where the growth of diamond crystal is disrupted due to the fluctuation of surrounding environments such as the amounts of radical species, temperature, and pressure. In one or more embodiments, nanocrystalline diamond layers are mainly comprised of small diamond crystals in nanospheres, or a nanocolumnar shape, and amorphous carbon distributed usually distributed in the positions between surrounding crystals or accumulate in the grain boundaries. Nanocrystalline diamond is used as a hard mask material in semiconductor applications because of its chemical inertness, optical transparency, and good mechanical properties.

One or more embodiments of the disclosure advantageously provide a novel method for the in situ nucleation and growth of nanocrystalline diamond films. Embodiments describe the development and utilization of plasma and gas chemistry for substrate treatment and the nucleation and growth of nanocrystalline diamond films. In one or more embodiments, prior solution-based substrate treatment/cleaning nor additional seeding methods such as sonication with nanodiamonds or mechanical scratching are not used. Likewise, no unique chemicals are required during the process.

Some embodiments of the disclosure advantageously provide a method of forming a nanocrystalline diamond film on an oxide-rich amorphous interfacial layer. Without being bound by theory, the inventors have found that the oxide-rich interfacial layer stands in contrast to previously reported interfacial layers which are essentially SiC. Further, it is believed that the presence of an oxide interfacial layer provides a divergent understanding of the growth mechanics of NCD films and may enable growth on previously unreported substrate materials.

In one or more embodiments, a nanocrystalline diamond layer is formed on a substrate. The process of one or more embodiments advantageously produces a nanocrystalline diamond layer with high density, high hardness, high etch selectivity, low stress, and excellent thermal conductivity.

Hard masks are used as etch stop layers in semiconductor processing. Ashable hard masks have a chemical composition that allows them to be removed by a technique referred to as ashing once they have served their purpose. An ashable hard mask is generally composed of carbon and hydrogen with trace amounts of one or more additional elements (e.g., nitrogen, fluorine, boron, silicon).

In a typical application, after etching, the hard mask has served its purpose and is removed from the underlying layer. This is generally accomplished, at least in part, by ashing, also referred to as “plasma ashing” or “dry stripping.” Substrates with hard masks to be ashed, generally partially fabricated semiconductor wafers, are placed into a chamber under vacuum, and oxygen is introduced and subjected to radio frequency power, which creates oxygen radicals and ions (i.e., oxygen plasma). The plasma reacts with the hard mask to oxidize it to water, carbon monoxide, and carbon dioxide. In some instances, complete removal of the hard mask may be accomplished by following the ashing with additional wet or dry etching processes, for example when the ashable hard mask leaves behind any residue that cannot be removed by ashing alone.

Hard mask layers are often used in narrow and/or deep contact etch applications, where photoresist may not be thick enough to mask the underlying layer. This is especially applicable as the critical dimension shrinks.

V-NAND, or 3D-NAND, structures are used in flash memory applications. V-NAND devices are vertically stacked NAND structures with a large number of cells arranged in blocks. As used herein, the term “3D-NAND” refers to a type of electronic (solid-state) non-volatile computer storage memory in which the memory cells are stacked in multiple layers. 3D-NAND memory generally includes a plurality of memory cells that include floating-gate transistors. Traditionally, 3D-NAND memory cells include a plurality of NAND memory structures arranged in three dimensions around a bit line.

An important step in 3D-NAND technology is slit etch. As the number of tiers increases in each technology node, to control the slit etch profile, the thickness of the hard mask film has to proportionally increase to withstand high aspect etch profiles. Currently, amorphous carbon (aC:H) films are used due to high hardness and ease of removal after the slit etch. However, amorphous carbon hard mask films have delamination concerns and poor morphology, leading to pillar striations.

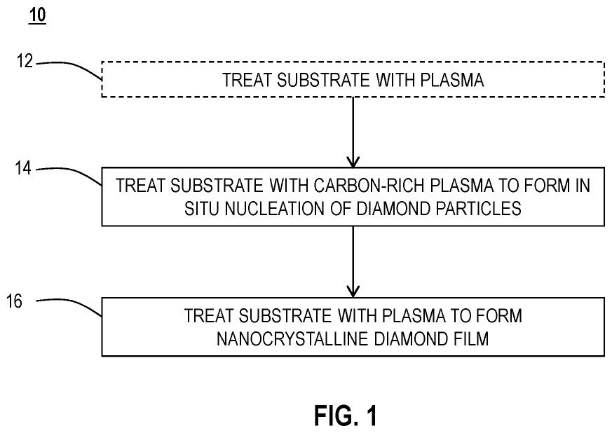

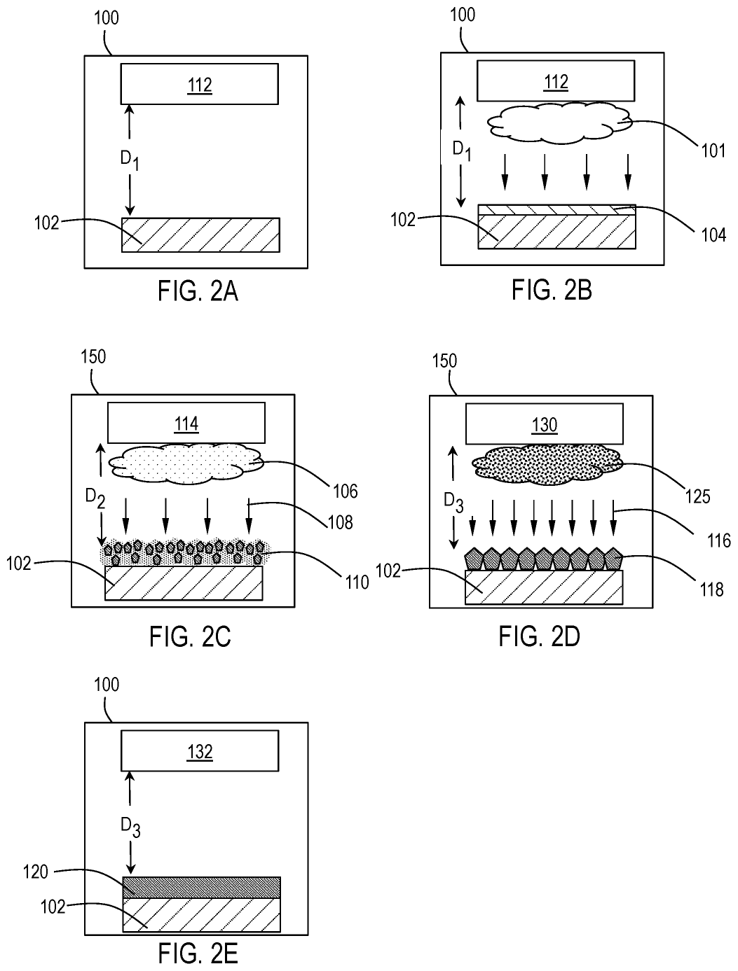

One or more embodiments of the disclosure are described with reference to the Figures. FIG. 1 illustrates a process flow diagram of a method 10 according to one or more embodiments. FIGS. 2A through 2E illustrate schematic cross-sectional view of a substrate 102 being processed according to the method 10 of one or more embodiments.

Referring to FIGS. 1 and 2A-2B, a method 10 of forming a nanocrystalline fully coalesced diamond film 120 is described. In some embodiments, the method 10 comprises, at operation 12, treating a substrate 102 with a first plasma 101 from a first plasma source 112 to form a treated substrate 104. The substrate 102 surface is exposed to a first plasma 101 in the first plasma process chamber 100 for a first plasma time period T_{P1} to form treated substrate 104.

The first plasma process chamber 100 can be any suitable plasma chamber with any suitable plasma source, such as, but not limited to, remote, microwave, capacitively coupled plasma (CCP), or inductively coupled plasma (ICP). In some embodiments, flow rates and other processing parameters described below are for a 300 mm substrate. It should be understood these parameters can be adjusted based on the size of the substrate processed and the type of chamber used without diverging from the methods disclosed herein. In specific embodiments, the first plasma 101 comprises one or more of a capacitively coupled plasma, inductively coupled plasma, pulsed discharge plasma, microwave plasma, hot filament, or electron cyclotron resonance plasma.

In some embodiments, the first plasma 101 comprises one or more of an organic species having the empirical formula CₓH_{y} where y≥x, argon (Ar), nitrogen gas (N₂), carbon dioxide (CO₂), or hydrogen gas (H₂).

In some embodiments, the first plasma 101 is generated with a power greater than or equal to about 50 watts, greater than or equal to about 100 watts, or greater than or equal to about 150 watts. In one or more embodiments, the plasma treatment may occur at any suitable power. In one or more embodiments, the power is greater than or equal to about 50 W. In other embodiments, the power is in a range of from about 50 W to about 12 kW, or in a range of from about 100 W to about 10 kW, or in a range of from about 100 W to about 5 kW, or in a range of from about 100 W to about 1 kW.

In some embodiments, the substrate 102 is maintained at a temperature in the range of from about 20° C. to about 600° C. during formation of the treated substrate 104.

In some embodiments, forming the treated substrate 104 comprises at least one cycle of exposure to the first plasma 101. In some embodiments, forming the treated substrate 104 comprises in the range of 1 to about 1000 cycles of exposures to the first plasma 101.

The first plasma process chamber 100 of some embodiments comprises a first plasma source 112, which may include one or more of a showerhead, electrodes, resonators, linear antenna, and the like. In one or more embodiments, the first plasma source 112 is positioned at a first distance D₁ from the top surface of the substrate 102. In some embodiments, the first distance, D₁, is greater than or equal to 10 mm, 15 mm, 20 mm, or 25 mm.

While not shown in the Figures, in some embodiments, operation 12 forms an oxide-rich amorphous layer directly on the substrate 102. Stated differently, in some embodiments, the treated substrate 104 comprises an oxide-rich amorphous layer. At this point of method 10, the oxide-rich amorphous layer comprises about 50 to about 70 atomic percent of oxygen. In some embodiments, the oxide-rich amorphous layer comprises about 5 to about 75, about 10 to about 75, about 20 to about 70, about 35 to about 70 or about 50 to about 70 atomic percent oxygen. At this point of the method 10, the oxide-rich amorphous layer has a thickness of less than or equal to about 5 nm, less than or equal to about 10 nm, less than or equal to about 20 nm, or less than or equal to about 50 nm.

Referring to FIG. 1 and FIG. 2C, at operation 14, the treated substrate 104 is incubated with a carbon-rich gas stream 108 and a second plasma 106 to nucleate diamond particles forming a diamond nuclei layer 110 on the top surface of the substrate 102. In some embodiments, the diamond nuclei layer 110 on the substrate 102 (or the treated substrate 104) is referred to as the seeded substrate.

In one or more embodiments, the diamond nuclei layer 110 is formed in a second plasma process chamber 150 with a second plasma 106 generated by a second plasma source 114. In other embodiments, not shown, the diamond nuclei layer 110 is formed in the first plasma process chamber 100 with a second plasma 106 generate by first plasma source 112. In some embodiments, the second plasma 106 can be generated by the first plasma source 112 but using different gases (compositions).

The second plasma process chamber 150 and the first plasma process chamber 100 can be any suitable plasma chamber with any suitable plasma source, such as, but not limited to, remote, microwave, capacitively coupled plasma (CCP), or inductively coupled plasma (ICP). In some embodiments, flow rates and other processing parameters described below are for a 300 mm substrate. It should be understood these parameters can be adjusted based on the size of the substrate processed and the type of chamber used without diverging from the embodiments disclosed herein. In specific embodiments, the second plasma 106 comprises one or more of a capacitively coupled plasma, inductively coupled plasma, pulsed discharge plasma, microwave plasma, hot filament, or electron cyclotron resonance plasma.

In some embodiments, the gas stream 108 (and the resulting second plasma 106) comprises a hydrocarbon. In one or more embodiments, the hydrocarbon has a general formula of CₘHₙ, where m is in a range from 1 to 120, and n is in a range of from 2 to 242. In specific embodiments, the hydrocarbon is selected from one or more of methane (CH₄), ethane (C₂H₆), propane (C₃H₈), butane (C₄H₁₀), pentane (C₅H₁₂), hexane (C₆H₁₄), heptane (C₇H₁₆), ethene (C₂H₄), propene (C₃H₆), butene (C₄H₈), pentene (C₅H₁₀), hexene (C₆H₁₂), heptane (C₇H₁₄), ethyne (C₂H₂), propyne (C₃H₄), butyne (C₄H₆), pentyne (C₅H₈), hexyne (C₆H₁₀), and heptyne (C₇H₁₂).

In one or more embodiments, the second plasma 106 may include, in addition to the hydrocarbon, one or more of argon (Ar), nitrogen gas (N₂), carbon dioxide (CO₂), or hydrogen gas (H₂). In one or more embodiments, the gas stream 108 comprising the hydrocarbon is co-flowed with one or more of argon (Ar), nitrogen gas (N₂), carbon dioxide (CO₂), or hydrogen gas (H₂) during plasma generation. In one or more embodiments, the gas stream 108 comprises from 5% to 90% hydrocarbon.

In some embodiments, the second plasma 106 is generated with a power less than or equal to about 15 kilowatts (kW), less than or equal to about 12 kW, less than or equal to about 10 kW, less than or equal to about 8 kW, less than or equal to about 6 kW, less than or equal to about 5 kW, or less than or equal to about 4 kW. In some embodiments, the gas stream 108 is ignited at a power of less than or equal to about 12 kW to form the second plasma 106. In some embodiments, the second plasma 106 is a pulsed plasma with a duty cycle less than or equal to 90%, less than or equal to 70%, less than or equal to 65%, less than or equal to 60%, less than or equal to 55%, less than or equal to 50%, less than or equal to 45% or less than or equal to 40% at a frequency in the range of about 20 Hz to about 5000 Hz, in the range of about 60 Hz to about 90 Hz, or in the range of about 70 Hz to about 80 Hz. In some embodiments, the second plasma 106 has a power less than or equal to about 6 kW with a duty cycle less than or equal to 50% at a frequency in the range of about 70 Hz to about 80 Hz. In some embodiments, the substrate 102 (or treated substrate 104) is maintained at a temperature in the range of about 50° C. to about 600° C. during formation of the diamond nuclei layer 110.

In some embodiments, the substrate 102 (or treated substrate 104) is incubated with the gas stream 108 and the second plasma 106 for a time period in a range of 1 second to about 10 hours. In some embodiments, the substrate 102 (or treated substrate 104) is incubated with the gas stream 108 and the second plasma 106 for a time period of less than or equal to about 4 hours, less than or equal to about 3 hours, less than or equal to about 2 hours, or less than or equal to about 1 hour.

In some embodiments, the substrate 102 (or treated substrate 104) is positioned at a second distance D₂ from first plasma source 112 or second plasma source 114. In some embodiments, the substrate 102 (or treated substrate 104) is positioned at a second distance D₂ less than or equal to about 12 cm, less than or equal to about 10 cm, or less than or equal to about 8 cm from the first plasma source 112 or from the second plasma source 114. In some embodiments, the second distance is greater than or equal to 1 cm. In some embodiments, the first plasma source 112 or from the second plasma source 114 comprises a showerhead which acts as an electrode. In some embodiments, the second plasma source 114 comprises a microwave plasma source.

While not shown in the Figures, in some embodiments, operation 14 forms the oxide-rich amorphous layer directly on the substrate surface. Alternatively, in some embodiments, the oxide-rich amorphous layer formed by operation 12 is still present after operation 14. Regardless of when it is formed, it can be stated differently that, in some embodiments, the seeded substrate comprises an oxide-rich amorphous layer. Further, the oxide-rich amorphous layer is directly on the substrate 102, between the diamond nuclei layer 110 and the substrate 102. At this point of method 10, the oxide-rich amorphous layer comprises at least 5 atomic percent or at least 20 atomic percent of oxygen. At this point of the method 10, the oxide-rich amorphous layer has a thickness of less than or equal to about 50 nm, less than or equal to about 20 nm, less than or equal to about 10 nm, less than or equal to about 5 nm, or less than or equal to about 3 nm.

At operation 16, a nanocrystalline diamond film 118 is grown from the diamond nuclei layer 110. As used in this manner, the term “grown” means that the nanocrystalline diamond film 118 is formed from the diamond nuclei layer 110 and may incorporate the diamond nuclei layer 110 into the nanocrystalline diamond film 118. The nanocrystalline diamond film 118 can be epitaxially grown or deposited by any suitable technique known to the skilled artisan.

In some embodiments, growing the nanocrystalline diamond film 118 occurs in the second plasma process chamber 150 using a third plasma 125. In other embodiments, growing the nanocrystalline diamond film 118 occurs in the first plasma process chamber 100 using a third plasma 125. Thus, in one or more embodiments, the first plasma process chamber 100 and the second plasma process chamber 150 are the same chamber. In some embodiments, the nanocrystalline diamond film 118 is grown using a conductively or inductively coupled plasma, microwave plasma, pulsed discharge plasma, microwave plasma, hot filament, or electron cyclotron resonance plasma. In some embodiments, the nanocrystalline diamond film 118 is grown using a microwave plasma.

In some embodiments, the third plasma 125 comprises a microwave plasma having a power greater than or equal to about 50 W, greater than or equal to about 100 W, greater than or equal to about 500 W, greater than or equal to about 1000 W (1 kW), greater than or equal to about 3 kW, or greater than or equal to about 5 kW with a duty cycle greater than or equal to about 60%, greater than or equal to about 70%, or greater than or equal to about 80%.

In some embodiments, the substrate 102 is maintained at a temperature in the range of about 25° C. to about 750° C. during exposure to the third plasma 125. In some embodiments, the substrate 102 is maintained at a temperature greater than or equal to about 25° C., greater than or equal to about 50° C., greater than or equal to about 75° C., greater than or equal to about 100° C., greater than or equal to about 150° C., greater than or equal to about 200° C., or greater than or equal to about 250° C. during exposure to the third plasma 125.

During operation 16, the substrate 102 is positioned a distance D₃ from the third plasma source 130. In some embodiments, the third plasma 125 can be generated by the first plasma source 112 and/or the second plasma source 114 but using different gases (compositions) or by a different third plasma source 130. In some embodiments, the distance D₃ is the same as the distance D₂. In some embodiments, the third distance D₃ is less than the second distance D₂. In some embodiments, the substrate 102 is positioned at a distance from the third plasma source 130, or from the first plasma source 112, or from the second plasma source 114, of less than or equal to about 12 cm, less than or equal to about 10 cm, or less than or equal to about 8 cm.

With reference to FIG. 2E, in one or more embodiments, after being subjected to an extended period of main growth, the high nucleation density on the seeded substrate leads to the formation of a fully coalesced nanocrystalline diamond film 120. In one or more embodiments, FIG. 2E illustrates how the fully coalesced nanocrystalline diamond film 120 looks after method 10 is complete. The difference between nanocrystalline diamond film 118 and fully coalesced nanocrystalline diamond film 120 is that in the nanocrystalline diamond film 118, the diamond nuclei from diamond nuclei layer 110 grow in size to become individual, larger diamond particles. These larger diamond particles are, however, isolated from each other. As these large diamond particles continue to grow in size, they eventually come into contact with the neighboring particles and begin to merge/coalesce with each other. This forms a dense, packed nanocrystalline diamond film, which becomes the fully coalesced nanocrystalline diamond film 120.

While not shown in the Figures, in some embodiments, operation 16 forms the oxide-rich amorphous layer directly on the substrate surface. Alternatively, in some embodiments, the oxide-rich amorphous layer formed by operation 12 or operation 14 is still present after operation 16. Regardless of when it is formed, it can be stated differently that, in some embodiments, the substrate comprises an oxide-rich amorphous layer. Further, the oxide-rich amorphous layer is directly on the substrate 102, between the full coalesced nanocrystalline diamond film 120 and the substrate 102. At this point of method 10, the oxide-rich amorphous layer comprises at least 5 atomic percent, at least 10 atomic percent, at least 20 atomic percent, or at least 30 atomic percent of oxygen. At this point of the method 10, the oxide-rich amorphous layer has a thickness of less than or equal to about 50 nm, less than or equal to about 20 nm, or less than or equal to about 10 nm.

One or more embodiments of the disclosure relate to an electronic device comprising a nanocrystalline diamond film. The nanocrystalline diamond film is directly on an interfacial oxide-rich amorphous layer, the oxide-rich amorphous layer is directly on a silicon substrate. In some embodiments, the electronic device is formed by the methods disclosed herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a nanocrystalline diamond film, the method comprising:
exposing a silicon substrate to a first plasma from a first plasma source, the first plasma source comprising one or more of CₓH_{y} wherein y≥x, carbon dioxide (CO₂), hydrogen (H₂), nitrogen (N₂), and argon (Ar) to provide a treated substrate;
incubating the treated substrate with a gas stream and a second plasma to nucleate diamond particles and form a seeded substrate, the gas stream comprising a hydrocarbon; and
exposing the seeded substrate to a third plasma having a power greater than 50 W to form a nanocrystalline diamond film,
wherein after formation of the nanocrystalline diamond film, the nanocrystalline diamond film is directly on an oxide-rich amorphous layer which is directly on the silicon substrate.

2. The method of claim 1, wherein the hydrocarbon has a general formula of CₘHₙ, where m is in a range of from 1 to 120, and n is in a range of from 2 to 242.

3. The method of claim 2, wherein the gas stream further comprises one or more of carbon dioxide (CO₂), hydrogen (H₂), nitrogen (N₂), and argon (Ar).

4. The method of claim 3, wherein the gas stream comprises from 5% to 90% of the hydrocarbon.

5. The method of claim 1, wherein the treated substrate is maintained at a temperature of less than 600° C. during incubation.

6. The method of claim 1, wherein the diamond particles are maintained at a temperature in a range of from 100° C. to 750° C. during formation of the nanocrystalline diamond film.

7. The method of claim 1, wherein the substrate is exposed to the first plasma at a temperature in a range of from 20° C. to 600° C.

8. The method of claim 1, wherein the substrate is exposed to the first plasma at a distance of greater than 1 cm.

9. The method of claim 1, wherein when the treated substrate is incubated with the gas stream, the gas stream is about 1 cm to 10 cm away from the top surface of the treated substrate.

10. The method of claim 1, wherein when the diamond particles are exposed to the second plasma, the third plasma is less than 10 cm away from the top surface of the substrate.

11. The method of claim 1, wherein the oxide-rich amorphous layer has a thickness of less than or equal to about 50 nm.

12. The method of claim 1, wherein the treated substrate comprises an oxide-rich amorphous layer directly on the silicon substrate.

13. The method of claim 12, wherein the oxide-rich amorphous layer comprises about 5 to about 70 atomic percent of oxygen.

14. The method of claim 1, wherein the seeded substrate comprises an oxide-rich amorphous layer directly on the silicon substrate.

15. A method of forming a diamond film, the method comprising:
exposing a treated substrate to a gas stream to nucleate diamond particles on a top surface of the substrate, the substrate comprising an exposed amorphous oxide-rich layer, the gas stream comprising a hydrocarbon; and
exposing the diamond particles to a plasma having a power greater than 50 W to form a nanocrystalline diamond film on the top surface of the substrate,
wherein the substrate is not silicon.

16. The method of claim 15, wherein the hydrocarbon has a general formula of CₘHₙ, where m is in a range of from 1 to 120, and n is in a range of from 2 to 242.

17. The method of claim 16, wherein the gas stream further comprises one or more of carbon dioxide (CO₂), hydrogen (H₂), nitrogen (N₂), and argon (Ar).

18. The method of claim 17, wherein the gas stream comprises from 5% to 90% of the hydrocarbon.

19. The method of claim 15, wherein the amorphous oxide-rich layer has a thickness of less than or equal to about 50 nm.

20. An electronic device comprising:
a silicon substrate;
an amorphous oxide layer directly on the silicon substrate; and
a nanocrystalline diamond film directly on the amorphous oxide layer.
